(19) United States
(12) Patent Application Publication
(10) Pub. No.: US 2007/0187669 A1
(43) Pub. Date: Aug. 16, 2007

(54) Field effect transistor and a method for manufacturing the same

(75) Inventors: Tsutomu Tezuka, Yokohama-shi (JP); Tomohisa Mizuno, Yokohama-shi (JP); Koji Usuda, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Kabushiki Kaisha Toshiba, Tokyo (JP)

(21) Appl. No.: 11/783,930

(22) Filed: Apr. 13, 2007

Related U.S. Application Data
(62) Division of application No. 11/069,980, filed on Mar. 3, 2005.

(30) Foreign Application Priority Data
Mar. 5, 2004 (JP) 2004-062110

(51) Int. Cl. H01L 31/00

(52) U.S. Cl. 257/19

(57) ABSTRACT

A field effect transistor fabricated in a device isolation region includes a Si₁₋ₓGeₓ layer (0<x≦1) that a lattice strain is relaxed, a strained Si layer formed on the Si₁₋ₓGeₓ, a gate electrode insulatively disposed over a part of the strained Si layer, source and drain regions formed in the strained Si layer with the gate electrode being arranged between the source and drain regions; and a Si film covering side walls of the Si₁₋ₓGeₓ layer on ends of the device isolation region.

### CROSS-REFERENCE TO RELATED APPLICATIONS

This application is based upon and claims the benefit of priority from prior Japanese Patent Application No. 2004-062110, filed Mar. 5, 2004, the entire contents of which are incorporated herein by reference.

### BACKGROUND OF THE INVENTION

1. Field of the Invention

The invention relates to a field effect transistor as a device fabricating an integrated circuit, particularly to a field effect transistor using a channel of strained Si or SiGe and a method of manufacturing the same.

2. Description of the Related Art

For attaining higher efficiency of a CMOS circuit device, and higher functioning thereof is applied a method of increasing a drive current per a unit gate width by shortening the gate length of an individual transistor and thinning a gate insulating film. As a result, a transistor to provide a necessary drive current decreases in size and a greater packing density becomes possible. At the same time, a power consumption per a unit device can be reduced by lowering of a drive voltage.

However, in recent years a technical barrier for achieving required performance by reduction of the gate length becomes suddenly high. Use of channel materials of high mobility is effective for this circumstances to be relaxed. A strained Si or strained SiGe is an influential candidate for the channel materials of high mobility.

The strained Si has tensile strain in in-plain directions of the substrate. The band structure varies due to this tensile strain, and an electron and hole mobility increase in comparison with a non-strain Si.

The electron and hole mobility increase as the strain increases. Usually, the strained Si is formed on a lattice-relaxed SiGe of a greater lattice constant by an epitaxial growth. The strain in the strained Si layer increases as the Ge composition of the SiGe template increases. If a CMOS is formed of MOSFETs having strained Si channels, it allows a higher speed operation than the Si-CMOS of the same size.

On the other hand, the strained SiGe has a compressive strain in in-plain directions of the substrate. The band structure varies due to this compressive strain, particularly the hole mobility increases in comparison with unstrained SiGe. Further, when the Ge composition is larger than around 80%, the strained SiGe increases in electron mobility and hole mobility more than two times in comparison with the unstrained Si. An increase in the strain and Ge composition increases the electron and hole mobility. Accordingly, if the strain is the same, the maximal mobility increases in a pure Ge channel. If a CMOS is formed of MOSFETs having strained SiGe channels, it allows a higher speed operation than Si-CMOS of the same size.

The strained Si is usually formed on the lattice-relaxed SiGe formed on a bulk Si substrate (bulk strained Si). In contrast, a research group including the present inventors proposes a MOSFET combining this strained Si or strained SiGe with a SOI (Si-on-Insulator) structure, and further demonstrates an operation thereof (for example, refer to non-patent literatures 1: T. Mizuno, S. Takagi, N. Sugiyama, J. Koga, T. Tezuka, K. Usuda, T. Hatakeyama, A. Kurobe, and A. Toriumi, IEDM Technical Digests p. 934 (1999), and 2: T. Tezuka et al., IEDM Technical Digests, p. 946 (2001)). These devices have merits arising from a SOI structure such as a merit capable of decreasing junction capacitance and a merit capable of reducing the device size with decreased channel-impurity concentration as well as a merit obtained by the high carrier mobility of the strained Si or strained SiGe channel. Accordingly, if a CMOS logic circuit is configured in this structure, an operation of a higher speed with a lower power can be expected for the CMOS logic circuit.

However, when a conventional device isolation structure and device fabrication method are applied to such bulk strained Si-MOSFET, SOI type strained Si (strained SOI) or strained SiGe (strained SGOI: SiGe-on-Insulator) MOSFET, a part of the SiGe layer is exposed to a device isolation end and directly in contact with an oxide film. Because there is a high-density interface state on the interface between the SiGe and oxide film, a leakage current through this interface state may occur. Further, the interface state of high-density causes deterioration of reliability of a device.

As discussed above, when a conventional device isolation structure and device fabrication method are applied to the bulk strained Si-MOSFET, strained SOI or strained SGOI-MOSFET, a part of the SiGe layer is exposed to a device isolation end and directly in contact with an oxide film, resulting in occurrence of a leakage current or deterioration of reliability of the device.

### BRIEF SUMMARY OF THE INVENTION

An aspect of the invention provides a field effect transistor fabricated in a device isolation region, comprising: a Si₁₋ₓGeₓ layer (0<x≦1) whose lattice strain is relaxed; a strained Si layer formed on the Si₁₋ₓGeₓ; a gate electrode insulatively disposed over a part of the strained Si layer; source and drain regions formed in the strained Si layer with the gate electrode being arranged between the source and drain regions; and a Si film covering side walls of the Si₁₋ₓGeₓ layer on ends of the device isolation region.

Another aspect of the invention provides a method of manufacturing a field effect transistor comprising: forming a Si₁₋ₓGeₓ layer (0<x≦1) in island on an insulating film, the Si₁₋ₓGeₓ layer being relaxed in lattice strain; forming a strained Si film on end walls of the Si₁₋ₓGeₓ layer and an upper surface thereof; forming an gate electrode insulatively on a part of the strained Si layer; and forming source and drain regions using the gate electrode as a mask.

### BRIEF DESCRIPTION OF THE SEVERAL VIEWS OF THE DRAWINGS

FIG. 1 shows a plan view of a substantial part of a MOSFET according to a first embodiment of the invention;

FIG. 2 shows a sectional view of the substantial part of the MOSFET along 2-2 line of FIG. 1;

FIG. 3 shows a sectional view of the substantial part of the MOSFET along 3-3 line of FIG. 1;

FIGS. 4 to 15 show sectional views of semiconductor structures in processing steps of a method of manufacturing the MOSFET of the first embodiment;

FIG. 16 is a diagram showing a relation between a thickness of a side wall Si film and a surface Ge composition;

FIGS. 17 and 18 are diagrams of explaining modifications of a shape of a device isolation end in the first embodiment;

FIG. 19 shows a plan view of a substantial part of a MOSFET according to a second embodiment of the invention;

FIG. 20 shows a sectional view of the substantial part of the MOSFET along 20-20 line of FIG. 19;

FIG. 21 shows a sectional view of the substantial part of the MOSFET along 21-21 line of FIG. 19;

FIGS. 22 and 23 show sectional views of semiconductor structures in processing steps of a method of manufacturing the MOSFET of the second embodiment;

FIG. 24 shows a plan view of a substantial part of a MOSFET according to a third embodiment of the invention;

FIG. 25 shows a sectional view of the substantial part of the MOSFET along 25-25 line of FIG. 24;

FIG. 26 shows a sectional view of the substantial part of the MOSFET along 26-26 line of FIG. 24;

FIGS. 27 to 32 show sectional views of semiconductor structures in processing steps of a method of manufacturing the MOSFET of the third embodiment;

FIG. 33 shows a plan view of a substantial part of a MOSFET according to a fourth embodiment of the invention;

FIG. 34 shows a sectional view of the substantial part of the MOSFET along 34-34 line of FIG. 33;

FIG. 35 shows a sectional view of the substantial part of the MOSFET along 35-35 line of FIG. 33;

FIGS. 36 to 41 show sectional views of semiconductor structures in processing steps of a method of manufacturing the MOSFET of the fourth embodiment;

FIG. 42 shows a plan view of a substantial part of a MOSFET according to a fifth embodiment of the invention;

FIG. 43 shows a sectional view of the substantial part of the MOSFET along 34-34 line of FIG. 42; and

FIG. 44 shows a sectional view of the substantial part of the MOSFET along 35-35 line of FIG. 42.

### DETAILED DESCRIPTION OF THE INVENTION

Embodiments of the present invention will be described referring to drawings hereinafter.

### First Embodiment

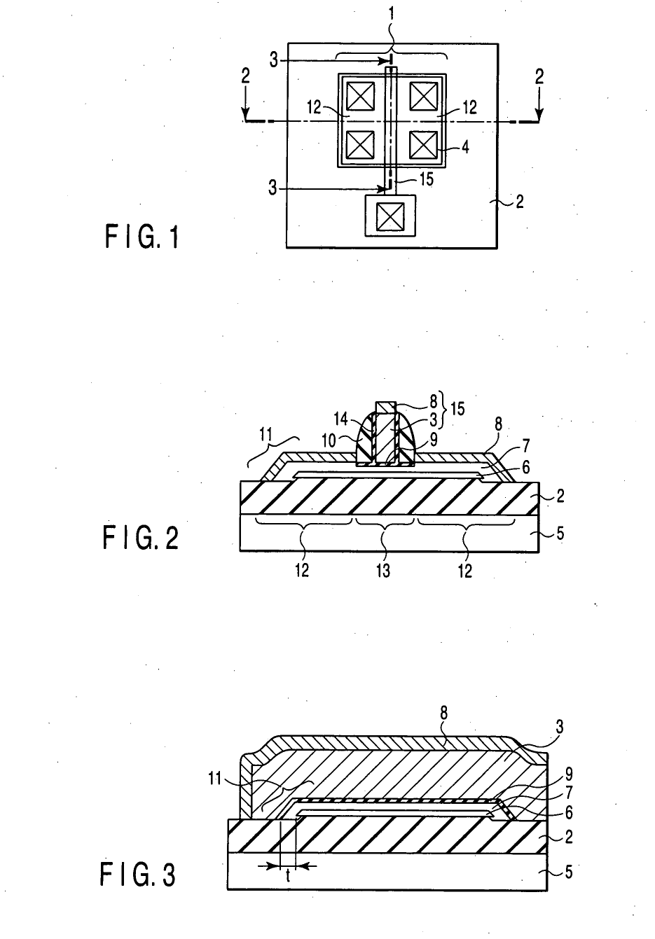

FIGS. 1 to 3 show a plan view and sectional views of a substantial part of a MOSFET concerning the first embodiment of the present invention.

On a Si substrate 5 of a plane direction (100) is formed a layered structure of a buried Si oxide film 2 of 100 nm in thickness, a lattice relaxation Si_{0.6}Ge_{0.4} layer 6 of 5 nm in thickness, and a strained Si layer 7 of 5 nm in thickness under a gate. The lattice-relaxed SiGe layer 6 relaxes the lattice by 88%. The strained Si layer 7 has a tensile strain of 1.45% in an in-plan direction. A device fabrication region 1 is an island shaped rectangular region as shown in FIG. 1 and includes a gate electrode 15, source and drain regions 12, and a contact hole 4.

In a cross section of the device in a gate length direction, a gate electrode 15 formed of a gate oxide film 9 made of a Si oxynitride film of 1.5 nm in thickness, a poly Si film 3 of 100 nm in thickness and 35 nm in width and an Ni silicide film 8 of 20 nm in thickness, which are sequentially laminated, is formed on a channel region 13 of the strained Si layer 7 as shown in FIG. 2. SiN gate side wall insulating films 10 of 20 nm in maximal thickness are formed on both sides of the gate electrode 15 with two 5 nm-thickness SiO₂ spacer layers 14 interposed between the insulating films 10 and the gate electrode 15.

In a cross section of the device in the gate width direction, an inner angle between the main surface of the SiGe layer 6 that is parallel with the substrate 2 and each of the side walls thereof makes an obtuse angle (larger than 90 degrees) at the device isolation end 11 as shown in FIG. 3. On the side walls of the SiGe layer 6 is laminated a Si layer of 15 nm in thickness t that is 10 nm thicker than the Si film 7 right under the gate oxide formed on the main surface of the SiGe layer 6.

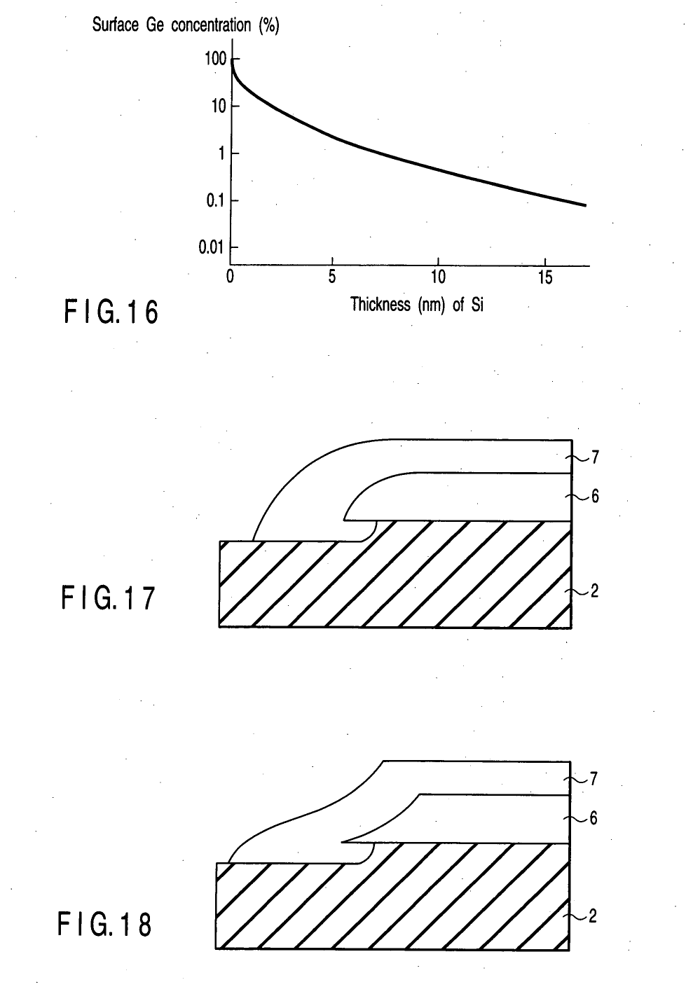

In the present embodiment, the thickness of the Si film on the side walls of the SiGe layer 6 is set based on a calculated result of a diffusion behavior of Ge shown in FIG. 16. FIG. 16 shows a result obtained by calculating a surface Ge composition when a Si thin film formed on a Si_{0.5}Ge_{0.5} film is annealed in a condition (1050° C., one second) employed in a real CMOS manufacturing process. If the Si film thickness is more than 10 nm, the surface Ge density becomes less than 1% so that the interface state is not almost affected.

In the present embodiment, the mobility of the strained Si layer 7 increases as the Ge composition of the SiGe layer 6 increases. On the other hand, if the strain becomes too large, lattice defects such as dislocations are generated and the surface roughening occurs. This trade off depends on conditions such as the degree of lattice relaxation of the SiGe layer 6 and the thickness of the strained Si layer 7. In the case of the present embodiment, because the thickness of the strained Si layer 7 is as thin as 5 nm, the above problem does not occurs even if the effective Ge composition xeff of the SiGe template layer 6 is increased to 0.5.

xeff is defined by a product Rx of a lattice relaxation rate R with a Ge composition x. The lattice relaxation rate represents degree of lattice relaxation, and it is defined by 1−Rεₚ/xε₀ where εₚ represents a lattice strain in a direction parallel with the main surface of the SiGe layer and ε₀ represents a mismatch strain of Si and Ge. When the SiGe template layer 6 is completely relaxed (R=1), an upper limit of x is 0.5, but when the lattice relaxation ratio is a one-half (R=0.5), the upper limit of x is 1. When the strained Si layer 7 is thinned to 3 nm for example, the upper limit of xeff increases to 0.7.

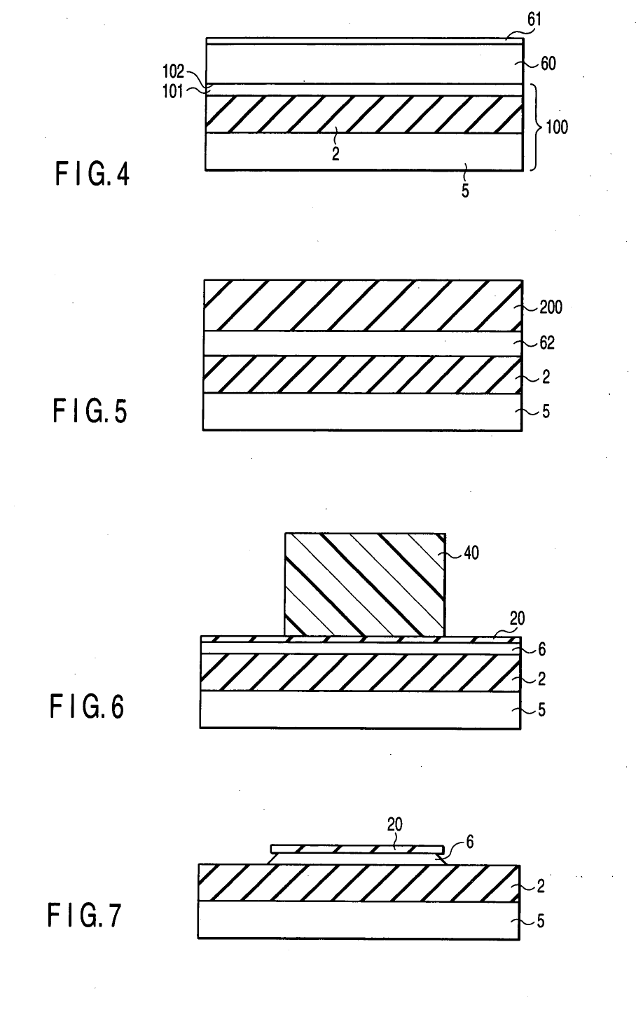

The manufacturing method of the present embodiment is described in conjunction with FIGS. 4 to 15 hereinafter.

In the step of FIG. 4, a SiGe film 60 of 150 nm in thickness which contains Ge composition of 15%, and a Si film 61 of 10 nm in thickness are epitaxially grown on a SOI substrate 100 by UHV-CVD, LP-CVD, MBE and the like. The SOI substrate 100 is formed of a Si oxide film 2 and a Si film 101 which are sequentially laminated on the Si substrate 5.

In the step of FIG. 5, the semiconductor structure of FIG. 4 is oxidized in oxygen ambient atmosphere at 1150° C. In this time, the interface 102 between Si and SiGe which exists before oxidation disappears by inter-diffusion. As a result, the layered structure of Si and SiGe becomes a single-layer structure of SiGe and an oxide film 200 is formed thereon. Ge atoms are rejected from the oxidized SiGe film and accumulated in the SiGe layer 62 so that the Ge composition of the SiGe layer. 62 increases. When the oxidation is done till the SiGe layer 62 becomes. 56 nm, the Ge composition of the SiGe layer 62 is 40%. Then, the lattice relaxation rate of SiGe layer 62 is 88%, and the effective Ge composition thereof is 0.35%.

After the thermal oxidation film 200 is removed by diluted hydrofluoric acid, etc., the SiGe layer 62 is thinned to the thickness of 5 nm by the steam oxidation at a low temperature (700° C. to 800° C.) to form a thin SiGe layer 6. The Ge composition of the SiGe layer 6 is held because Ge is taken in an oxide film in the case of the steam oxidation at a low temperature.

In the step of FIG. 6, after a SiO₂ film 20 of 3 nm in thickness is deposited on the SiGe layer 6 by CVD, a pattern corresponding to active regions (device fabrication regions) is formed with resist 40. After the SiO₂ film 20 is etched by RIE, the SiGe layer 6 is etched by CDE and then the resist 40 is removed by ashing.

In the step of FIG. 7, the cross-section of the end side wall of the SiGe layer 6 is tapered, an inner angle between the side wall and the main surface makes an obtuse angle.

In the step of FIG. 8, a Si film 70 of 10 nm in thickness is selectively grown on the side wall of the SiGe layer 6 by UHV-CVD, LP-CVD, etc.

In the step of FIG. 9, after the SiO₂ film 20 is removed by diluted hydrogen fluoride solution, etc., a Si layer 7 of 7 nm in thickness is selectively grown on the main surface and side wall of the SiGe layer again by UHV-CVD, LP-CVD, etc. This Si layer 7 becomes a Si layer having tensile strain in the main surface due to lattice mismatching with the furring lattice-relaxed SiGe layer, that is, a strained Si layer.

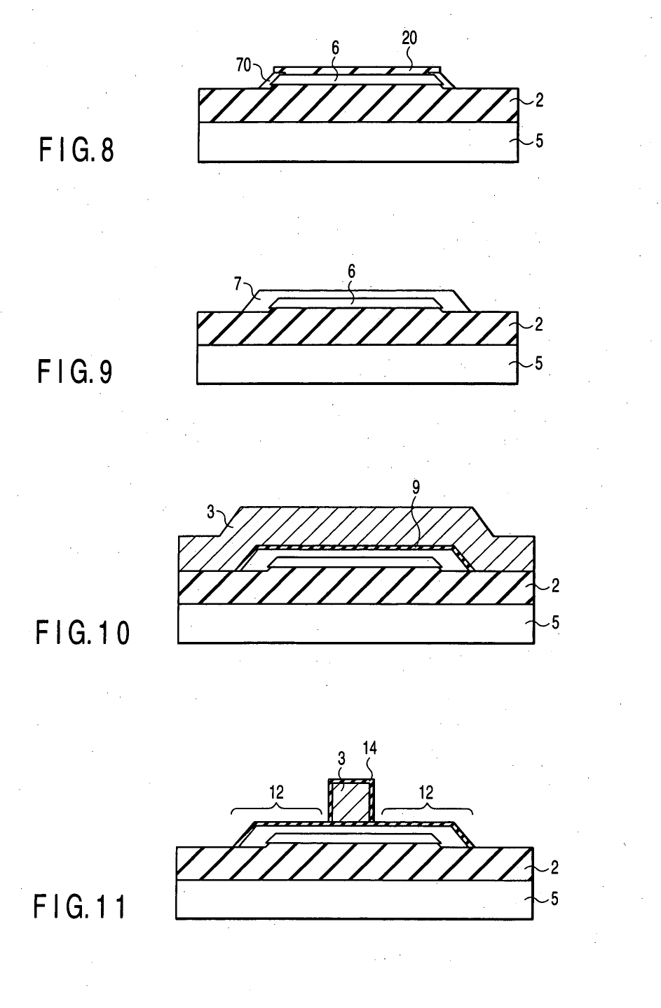

In the step of FIG. 10, a gate oxynitride film 9 of 1.5 nm in thickness is formed on the Si layer by thermal oxidation, plasma nitridation, etc., and then a polysilicon gate 3 of 100 nm in thickness is deposited on the gate oxynitride film 9. Ions of any one of phosphorous (P), arsenic (As), antimony (Sb) is implanted into the polysilicon gate 3 in the case of an n-channel transistor. Boron (B) ions or boron fluoride (BF2) ions are injected into the polysilicon gate 3 in the case of a p-channel transistor. Resist (not shown) is formed in a gate pattern by a photolithography and then it is processed in a gate shape by RIE.

In the step of FIG. 11, the post-oxidation is performed to form an oxide film 14 of 5 nm around the poly Si gate 3. Ions of any one of phosphorous (P), arsenic (As), antimony (Sb) in the case of an n-channel transistor, and boron (B) ions or boron fluoride (BF2) ions in the case of a p-channel transistor is injected into the source and drain regions 12 by a low energy of 5 keV to 10 keV.

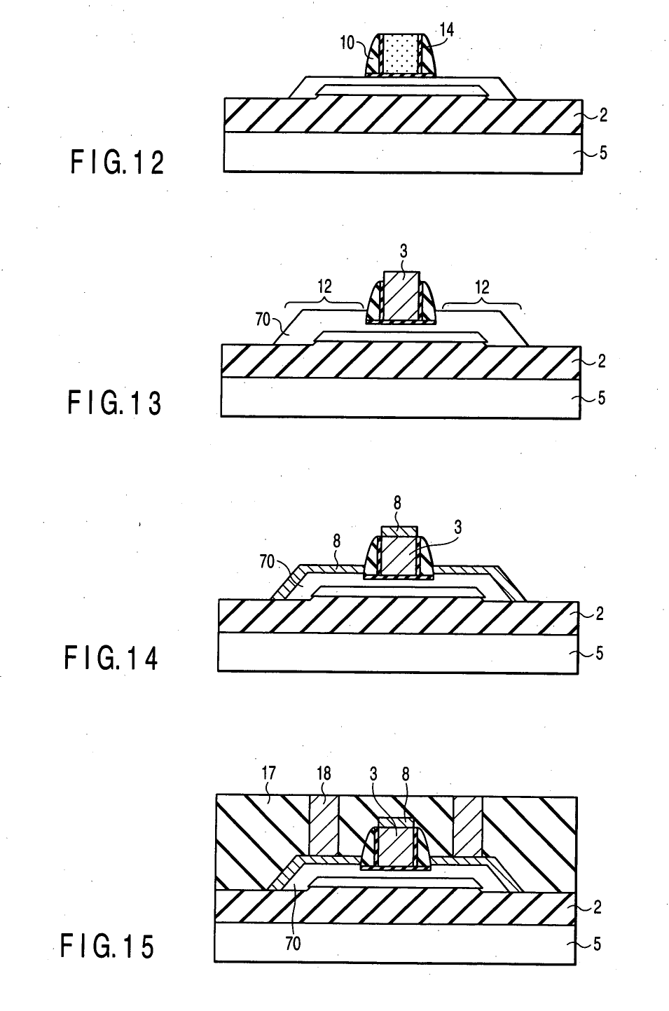

In the step of FIG. 12, after a nitride film 10 of 20 nm in thickness is deposited on the oxide film 14 by CVD to form a gate side wall insulating film 10 by RIE.

In the step of FIG. 13, a Si film 70 of 20 nm in thickness is selectively grown on the source and drain regions 12 and Si gate 3 by UHV-CVD, LP-CVD, etc.

Impurity ions are implanted to the source and drain regions 12. As ions are implanted in the region of nMOSFET by a dose of 2×10¹⁵ cm⁻² in 10 keV, and BF2 ions in the region of pMOSFET by a dose of 2×10¹⁵ cm⁻² in 8 keV. Subsequently, the impurity is activated by RTA at 1000° C., one second.

In the step of FIG. 14, Ni film of 20 nm in thickness is deposited on the source and drain regions 12 and the Poly Si gate 3, and annealed in nitrogen atmosphere of 500° C., 10 minutes to form a NiSi film 8 on the source and drain region 12 and the poly Si gate 3. Subsequently, a no-reaction Ni layer is removed with hydrochloric acid/hydrogen peroxide mixture liquid.

In the step of FIG. 15, after an interlayer insulating film 17 is deposited on the structure of FIG. 14, contacts 18 are formed on the source and drain 12 and the gate 3. At last, annealing is carried out at 450° C., 30 minutes in a diluted hydrogen ambient atmosphere, whereby a strained SOI-MOSFET of the present embodiment is completed.

In this way, according to the present embodiment, in a MOSFET having the strained Si channel wherein the strained Si layer 7 is provided on the lattice-relaxed SiGe layer 6, the Si film formed on the side wall of the device isolation end makes it possible to prevent the side wall of the lattice-relaxed SiGe layer 6 from being exposed to the device isolation end. Further, the oxide film formed on the side wall of the SiGe layer 6 makes it possible to prevent increase of a leakage current. As a result, reliability of the device can be improved. Also, since an inner angle between the side wall of the SiGe layer and the main surface thereof makes an obtuse angle, electric field convergence to the device isolation end is relaxed, resulting in further improving reliability of the device. If a CMOS logic circuit and the like are configured by the present structure, it is possible to realize a higher speed and lower power CMOS logic circuit.

Further, since the Si layer in the side wall of the SiGe layer 6 is formed to be more than 10 nm in thickness, it is possible to prevent increase of a leakage current due to a high-density of interface states, which arise from Ge diffusion to the layer surface by the annealing.

In particular, in the case of the strained Si channel, the Si film thickness of the side wall is set to be thicker than that of the Si film on the main surface on which the channel is formed. Thus, the strain of the device isolation end 11 is relaxed, resulting in higher threshold voltage around the device isolation end. As a result, it becomes possible to suppress generation of a parasitic channel.

A modification of the present embodiment provides a configuration wherein the shape of the device isolation end 11 has a convex curve or a concave curve as shown in FIG. 17 or 18. This configuration provides the same effect as the above embodiment. The SOI substrate can have (110)- or (111) -surface as well as (100)-surface.

### Second Embodiment

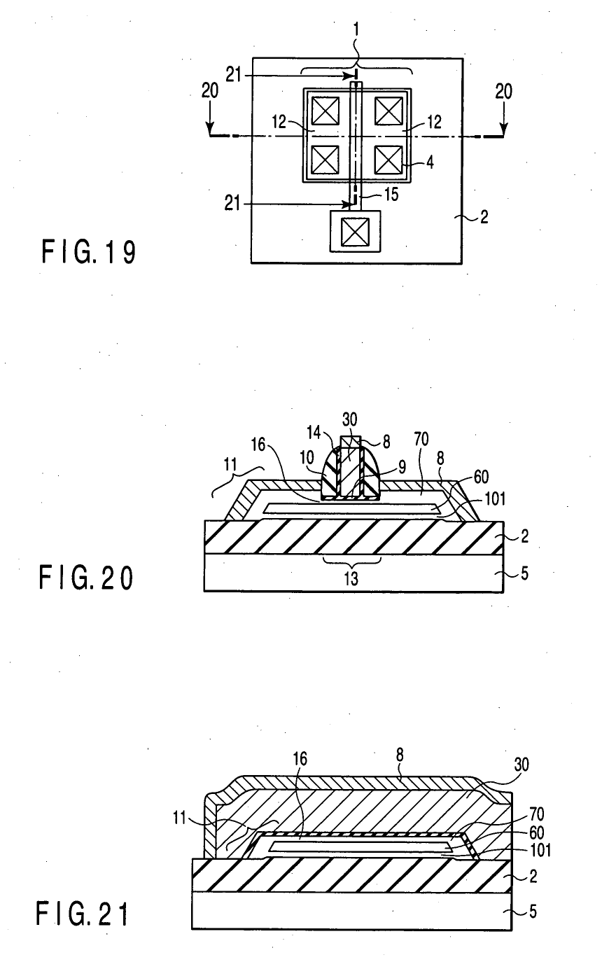

FIGS. 19 to 21 are plan view and sectional views of the substantial part of a MOSFET related to the second embodiment of the present invention. In the second embodiment, like reference numerals are used to designate like structural devices corresponding to those like in the first embodiment and any further explanation is omitted for brevity's sake.

On the Si substrate 5 with (100)-surface is formed a layered structure of a buried Si oxide film 2 of 100 nm in thickness, a Si layer 101 of 5 nm in thickness, a strained Si_{0.6}Ge_{0.4} layer 60 of 5 nm in thickness, and a Si layer of 2 nm in thickness (cap layer) 16. A device fabrication region 1 is an island shaped rectangular region as shown in FIG. 19, and includes a gate electrode 3, source and drain regions 12 and a contact hole 4.

In a cross section of the device in a gate length direction, a gate electrode 15 formed of a gate oxide film 9 made of a Si oxynitride film of 1.5 nm in thickness, a poly Si film 30 of 100 nm in thickness and 35 nm in width and an Ni silicide film 8 of 20 nm in thickness, which are sequentially laminated, is formed on a Si layer 16 on a SiGe layer 60 in a channel region 13 as shown in FIG. 20.

Si nitride gate side wall insulating films 10 of 20 nm in maximal thickness are formed on both sides of the gate electrode 15 with SiO₂ spacer layers 14 of 5 nm in thickness interposed between the insulating films 10 and the gate electrode 15. An inner angle between the side wall and the main surface of the SiGe layer 60 that is parallel with the substrate 2 makes an obtuse angle. On the side wall of the SiGe layer 60 is laminated a Si layer 70 of 15 nm in thickness.

In the present embodiment, the Si layer 16 as the cap layer is provided for preventing the SiGe layer 60 from being directly in contact with the oxide film. A channel is formed at an interface between the Si layer 16 and the strained SiGe layer 60. The Si cap layer 16 is not always needed, and may be omitted. In this case, the channel is formed not at the interface between the SiGe layer 60 and the Si layer 16, but at the interface between the gate oxynitride film 9 and the SiGe layer 60.

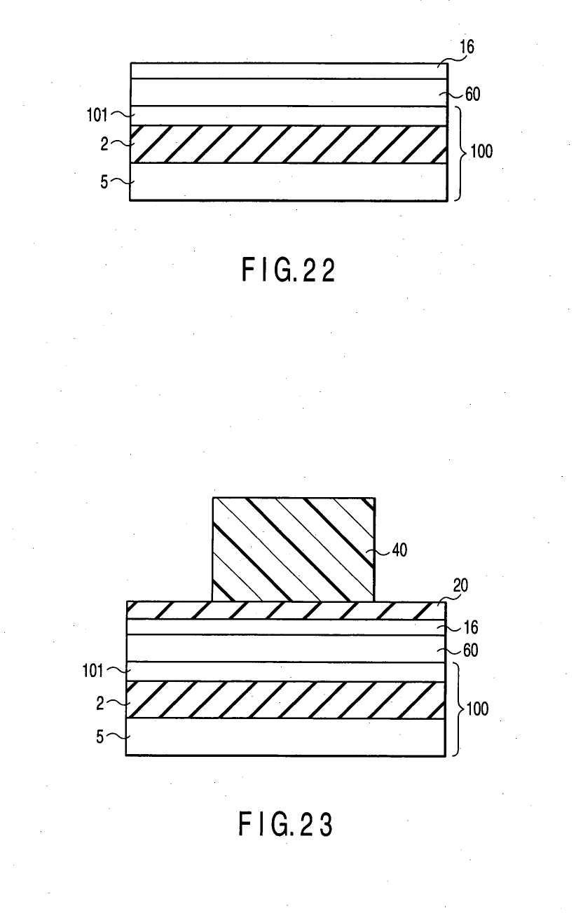

The manufacturing method of the present embodiment is described in conjunction with FIGS. 22 and 23 hereinafter.

In the step of FIG. 22, a SiGe film 60 of 5 nm in thickness which contains Ge composition of 40% and a Si film 16 of 3 nm in thickness are epitaxially grown on a SOI substrate 100 having a Si layer of 5 nm in thickness by UHV-CVD, LP-CVD, MBE, etc.

In the step of FIG. 23, after a SiO₂ film 20 of 3 nm in thickness is deposited on the Si layer 16 by CVD, a pattern corresponding to active regions is formed with resist 40. The steps after this step follows the steps of the first embodiment, that is, the steps on and after FIG. 7.

In the present embodiment, the shape of the device isolation end is a trapezoid as shown in FIG. 7, but may be a convex as shown in FIG. 17 or a concave as shown in FIG. 18. The SOI substrate can have (110)- or (111)-surface as well as (100)-surface. The Si layer 16 on the strained SiGe layer 60 may be omitted. In this case, the channel of the pMOSFET becomes a SiGe surface channel.

In this way, according to the present embodiment, in the MOSFET using the strained SiGe layer 60 for the channel, the Si film formed on the side walls of the device isolation end prevents the side wall of the SiGe layer 60 from being exposed to the device isolation end. Accordingly, the present embodiment has the same effect as the first embodiment.

### Third Embodiment

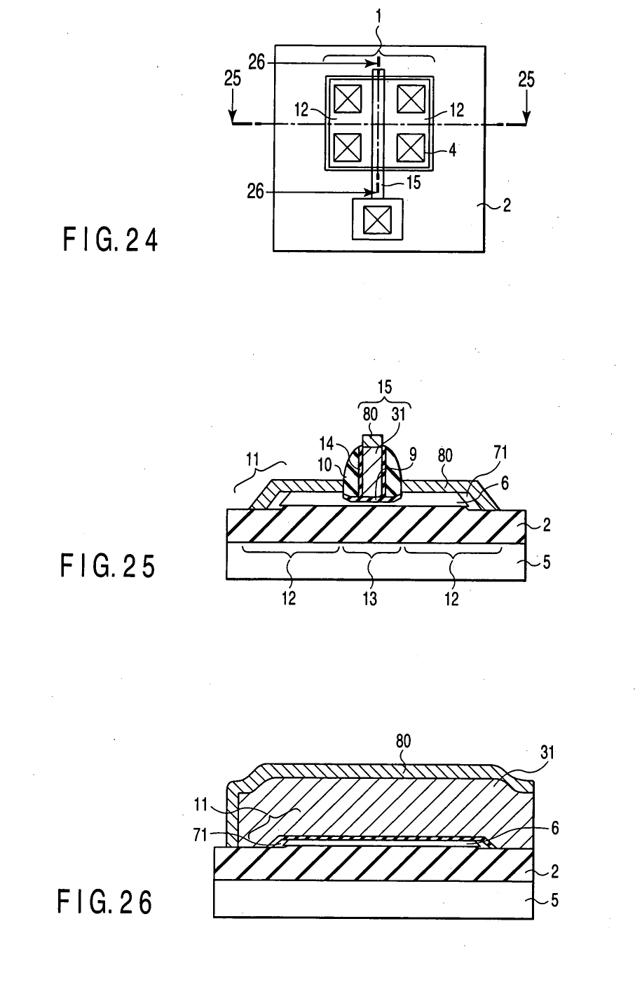

FIGS. 24 to 26 are a schematic plan view and sectional views of the substantial part of a MOSFET related to the third embodiment of the present invention. In the third embodiment, like reference numerals are used to designate like structural devices corresponding to those like in the first embodiment and any further explanation is omitted for brevity's sake.

A buried Si oxide film 2 of 100 nm in thickness and a Si 1-x. Ge x layer 6 are formed on a Si substrate 5 of plane direction (100). The thickness of the SiGe layer 6 and Ge composition x thereof are 20 nm and 0.11 in the source and drain regions 12, and 5 nm and 0.9 in the channel portion 13. The device fabrication region 1 is an island shaped rectangular region as shown in FIG. 24, and includes a gate electrode 15, source and drain regions 12, and a contact hole 4.

In a cross section of the device in a gate length direction, a gate electrode 15 formed of a gate oxide film 9 made of a Si oxynitride film of 1.5 nm in thickness, a poly Si film 31 of 100 nm in thickness and 35 nm in width and an Ni germano silicide film 80 of 20 nm in thickness, which are sequentially laminated, is formed on a Si_{0.1}Ge_{0.9} layer 6 of 5 nm in thickness in a channel region 13 as shown in FIG. 25. Si nitride gate side wall insulating films 10 of 20 nm in maximal thickness are formed on both sides of the gate electrode 15 with SiO₂ spacer layers 14 of 5 nm in thickness interposed between the insulating films 10 and the gate electrode 15.

In a cross section of the device in the gate width direction, an inner angle between the main surface of the SiGe layer 6 that is parallel with the substrate 2 and the side wall thereof makes an obtuse angle at the device isolation end 11 as shown in FIG. 26. A Si layer 71 of 15 nm in thickness is formed on the side wall of the SiGe layer 6. The thickness of the Si layer 71 is set based on a computed result of a diffusion behavior of Ge similarly to the first embodiment. This thickness hardly affect the interface state when the surface Ge density of the Si layer 71 is less than 1%.

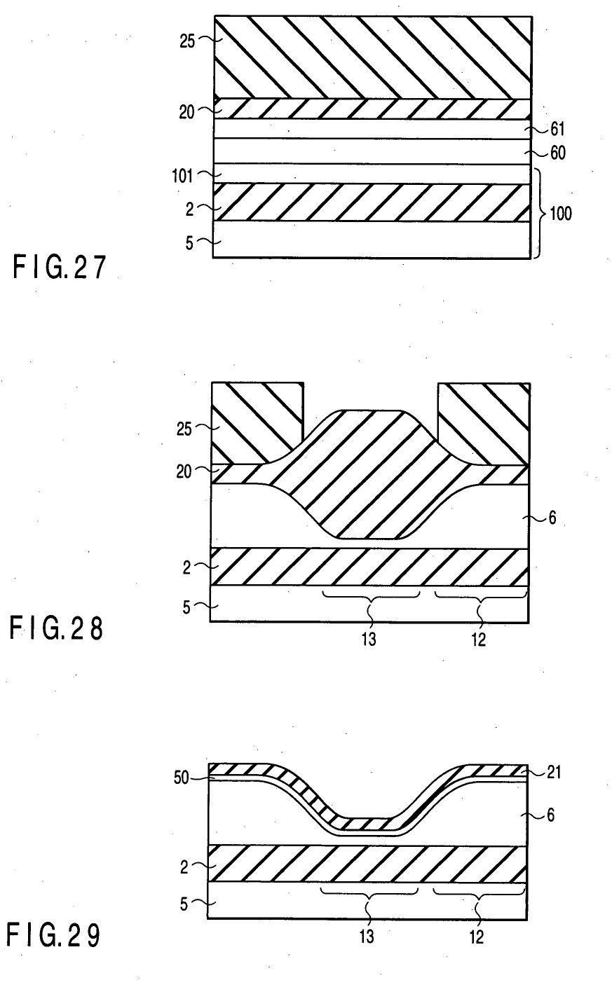

The manufacturing method of the present embodiment is described in conjunction with FIGS. 27 to 32 hereinafter.

In the step of FIG. 27, a SiGe film 60 of 20 nm in thickness which contains Ge composition of 23% and a Si film 61 of 10 nm in thickness are epitaxially grown on a SOI substrate 100 having a Si layer of 5 nm in thickness by UHV-CVD, LP-CVD, MBE, etc. A SiO₂ film 20 of 10 nm in thickness and a Si nitride film 25 of 100 nm in thickness are sequentially deposited on the Si film 61 by CVD. A window is formed on a part of the Si nitride 25 that corresponds to the channel region 13 by a photolithography.

In the step of FIG. 28, when the channel region 13 is thinned by thermal oxidation, the Ge composition increases only on this region. When the thickness of the SiGe film 60 on the channel region 13 becomes 5 nm, the oxidation is stopped. In this time, the Ge composition of the SiGe layer 6 in the channel region 13 is 90%, and the main surface has a compressive strain. On the other hand, Ge composition is uniformized in the source and drain regions 12 by inter-diffusion of Ge and Si. The source and drain regions 12 each contain Ge composition of 12%.

In the step of FIG. 29, the Si nitride 25 is removed by CDE, and then the oxide film 20 is removed with ammonium fluoride solution or diluted hydrofluoric acid solution. Thereafter, an amorphous Si film 50 of 2 nm in thickness is deposited on the SiGe layer 6 by MBE, CVD or electron beam evaporation, etc. Further, a SiO₂ film 21 of 5 nm in thickness is deposited on an amorphous Si film 50 by CVD.

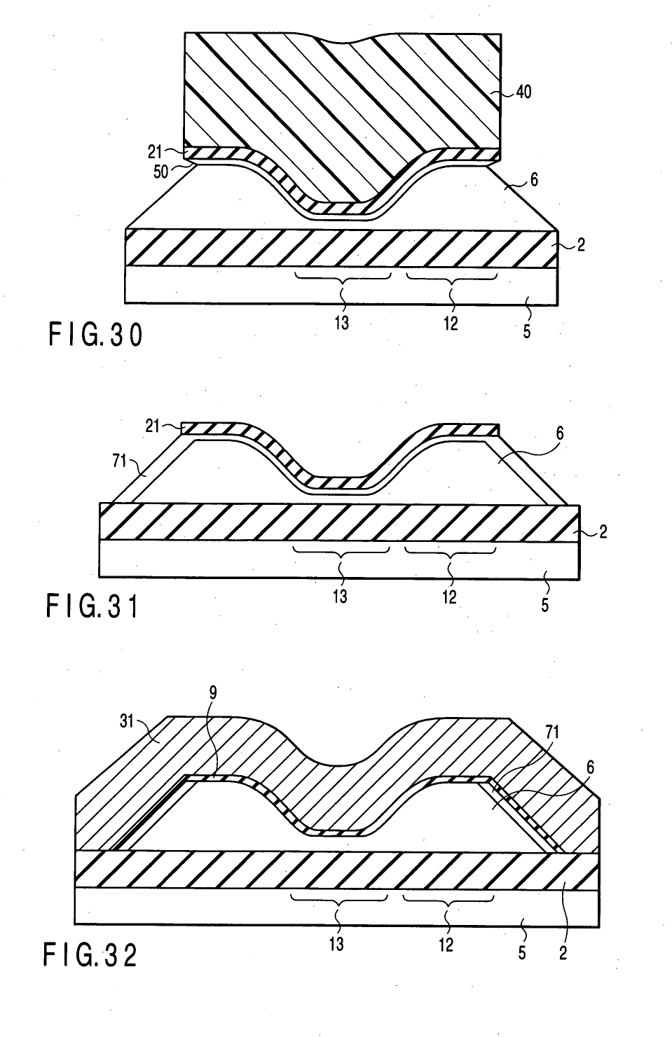

In the step of FIG. 30, a pattern for active regions is formed with resist 40 by a photolithography, and the SiO₂ film 21 is etched by RIE. Then, the SiGe 6 layer is etched by CDE.

In the step of FIG. 31, after removal of the resist 40, a Si film 71 is selectively grown on the side wall of an active region epitaxitially by UHV-CVD or LP-CVD. The amorphous Si film 50 is crystallized by solid-phase epitaxial growth in this epitaxial growth process.

In the step of FIG. 32, after exfoliation of the SiO₂ film 21, the crystallized Si film 50 is thermally oxidized entirely, and further subjected to a plasma nitriding process to form a gate insulating film 9. A poly SiGe gate electrode 31 is deposited on the gate insulating film 9. The steps after the step of FIG. 32 follows the steps of the first embodiment (the steps on and after FIG. 11).

In the present embodiment, the shape of the device isolation end may be a convex as shown in FIG. 17 or a concave as shown in FIG. 18 as well as a trapezoid shown in FIG. 9. The surface orientation of the SOI substrate may be (110) or (111) as well as (100).

### Fourth Embodiment

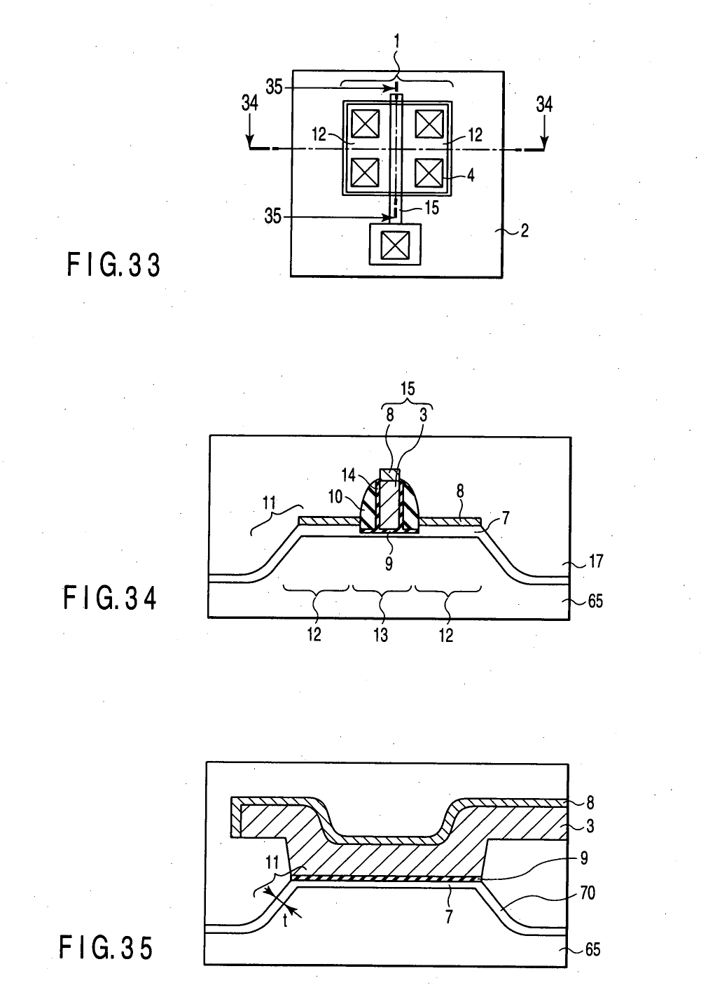

FIGS. 33 to 35 are a schematic plan view and sectional views of a substantial part of a MOSFET related to the fourth embodiment of the present invention. In the fourth embodiment, like reference numerals are used to designate like structural devices corresponding to those like in the first embodiment and any further explanation is omitted for brevity's sake.

The present embodiment uses as a device fabrication substrate a layered structure of a Si substrate, a thicker lattice-relaxed SiGe layer formed on the Si substrate and a strained Si layer formed on the SiGe layer. On a Si substrate (not shown) with (100)-surface is formed a layered structure of a lattice relaxation Si_{0.65}Ge_{0.35} layer 65 and a strained Si layer 7. The lattice-relaxed SiGe layer 65 is approximately completely lattice-relaxed. The strained Si layer 7 has an tensile strain of 1.45% in in-plane directions. The device fabrication region 1 is an islan shaped rectangular region as shown in FIG. 33 and includes a gate electrode 15, source and drain regions 12 and a contact hole 4.

In a cross section of the device in a gate length direction, a gate electrode 15 formed of a gate insulating film 9 made of a Si oxynitride film of 1.5 nm in thickness, a poly Si film 3 of 100 nm in thickness and 35 nm in width and an Ni silicide film 8 of 20 nm in thickness, which are sequentially laminated, is formed on a strained Si layer 7 of 8 nm in thickness in a channel region 13 as shown in FIG. 34.

Si nitride gate side wall insulating films 10 of 20 nm in maximal thickness are formed on both sides of the gate electrode 15 with SiO₂ spacer layers 14 of 5 nm in thickness interposed between the insulating films 10 and the gate electrode. In a cross section of the device in the gate width direction, an inner angle between the main surface of the SiGe layer 65 that is parallel with the substrate 2 and the side wall thereof makes an obtuse angle at the device isolation end 11 as shown in FIG. 35. A Si layer 70 is laminated on the side and bottom walls of the SiGe layer 65. The thickness t of the Si layer 7 on the side wall of the layer 65 is 15 nm that is 7 nm thicker than the Si layer 7 right under the gate oxynitride film on the main surface as shown in FIG. 35.

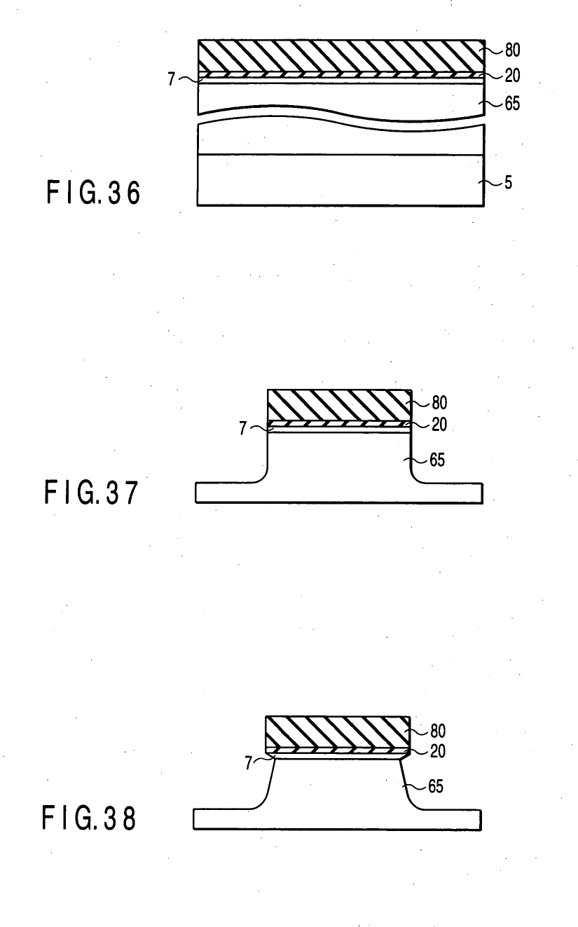

The manufacturing method of the present embodiment is described in conjunction with FIGS. 36 to 41 hereinafter.

In the step of FIG. 36, a SiGe film 65 of 0.1-5 μm in thickness and a Si film 7 of 8 nm in thickness is epitaxially grown on a Si substrate 5 by UHV-CVD, LP-CVD, MBE, etc. A SiO₂ film 20 of 3 nm in thickness and a Si nitride film 80 of 100 nm in thickness are sequentially deposited on the Si film 7 by CVD.

In the step of FIG. 37, a pattern corresponding to active regions is formed by a photolithography. The nitride film 80, oxide film 20, Si film 7 and part of the SiGe layer 65 are etched by RIE.

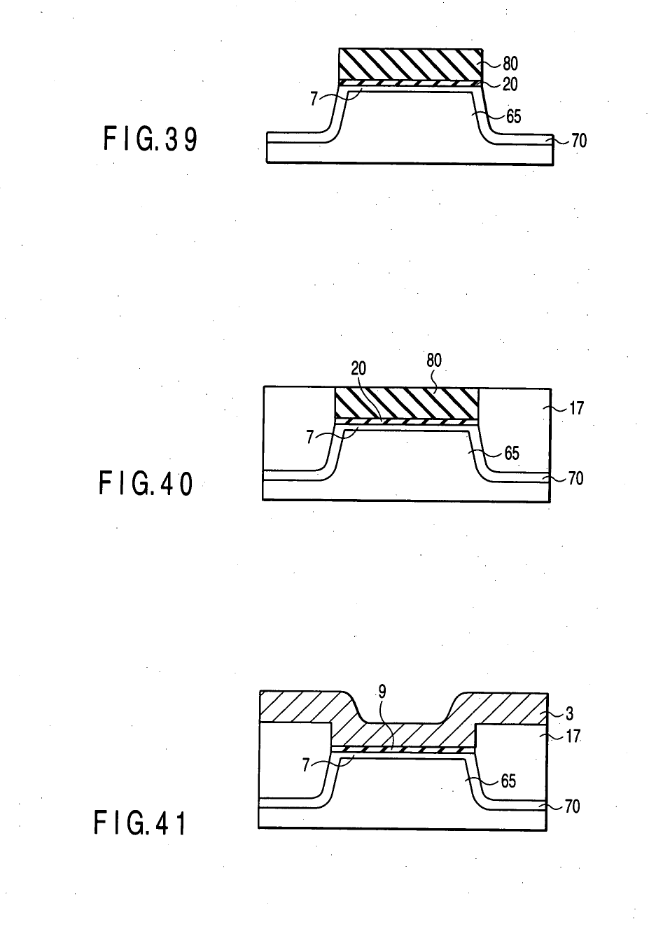

In the step of FIG. 38, when the SiGe layer 65 is etched by CDE, a sectional shape of the end of the SiGe layer 65 has a slight tapered shape so that an inner angle between the side wall of the SiGe layer 65 and the main surface thereof becomes an obtuse angle. In the step of FIG. 39, the Si film 70 of 3 nm in thickness is selectively grown on the side of SiGe layer 65 by UHV-CVD, LP-CVD, etc.

In the step of FIG. 40, an interlayer insulating layer 17 is deposited on the Si films 7 and 70 by CVD and then the surface is planarized by the chemical mechanical polishing (CMP) to expose the top of the Si nitride 80. In the step of FIG. 41, after removal of the Si nitride film 80 and the Si oxide film 20, the gate oxynitride film 9 of 1.5 nm in thickness is formed on the Si film by thermal oxidation and plasma nitriding, etc. Further, the polysilicon gate 3 of 100 nm in thickness is deposited on the gate insulating film 9.

The steps after the step of FIG. 41 follows the steps on and after the step of forming the gate (on and after FIG. 11) in the first embodiment. In this manner a structure shown in FIGS. 33 to 35 is provided.

According to the present embodiment, in a MOSFET having the strained Si channel wherein the strained Si layer 7 is arranged on the convex of the lattice-relaxed SiGe layer 65, the Si film 70 formed on the side of the device isolation end (convex side) prevents the side portion of the lattice-relaxed SiGe layer 65 from exposing to the device isolation end.

Accordingly, increase of a leakage current occurring by the oxide film formed on the surface of the SiGe layer 65 can be prevented, and the present embodiment has the same effect as the first embodiment.

### Fifth Embodiment

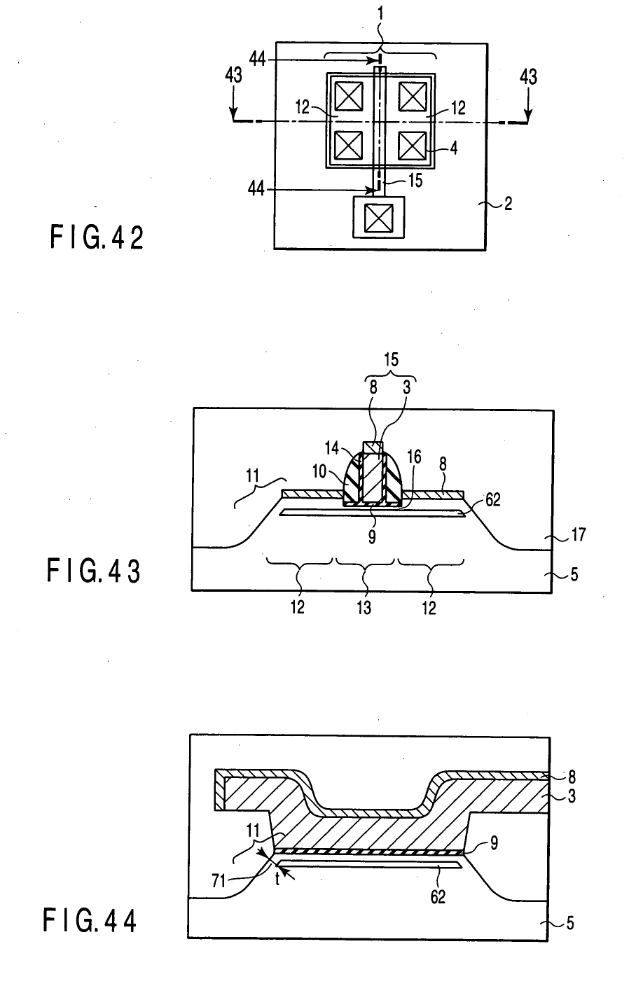

FIGS. 42 to 44 are a schematic plan view and sectional views of a substantial part of a MOSFET related to the fifth embodiment of the present invention. In the fifth embodiment, like reference numerals are used to designate like structural devices corresponding to those like in the first embodiment and any further explanation is omitted for brevity's sake.

The present embodiment uses a strained SiGe layer formed on a Si substrate as a device fabrication substrate. On a Si substrate 5 with (100)-surface is formed a layered structure of a strained Si_{0.6}Ge_{0.4} layer 62 of 10 nm in thickness and a Si cap layer 16. The device fabrication region 1 is an island shaped rectangular region as shown in FIG. 42 and includes a gate electrode 15, source and drain regions 12 and a contact hole 4.

In a cross section of the device in a gate length direction, a gate electrode 15 formed of a gate oxide film 9 made of a Si oxynitride film of 2 nm in thickness, a poly Si film 3 of 100 nm in thickness and 35 nm in width and an Ni silicide film 8 of 20 nm in thickness, which are sequentially laminated, is formed on a cap layer 16 of 1.5 nm in thickness on a channel region 13 as shown in FIG. 43. Si nitride gate side wall insulating films 10 of 20 nm in maximal thickness are formed on both sides of the gate electrode 15 with SiO₂ spacer layers 14 of 5 nm in thickness interposed between the insulating films 10 and the gate electrode 15.

In a cross section of the device in the gate width direction, an inner angle between the main surface of the SiGe layer 62 that is parallel with the substrate 5 and the side wall thereof makes an obtuse angle at the device isolation end 11 as shown in FIG. 44. A Si film 71 is formed on the side wall of the SiGe layer 62. The thickness t of the Si film 71 on the side wall of the SiGe layer 62 shown in FIG. 44 is 15 nm.

The manufacturing method of the present embodiment is common to the steps (FIGS. 13 and 14) of the fourth embodiment except for using a substrate wherein the strained Si_{0.6}Ge_{0.4} layer Si 62 and the Si cap layers 16 are epitaxially grown on a Si substrate.

The Si cap layer 16 is not always needed, and may be omitted. In this case, a channel is formed on the surface of the SiGe layer 62 rather than an interface between the SiGe layer 62 and the Si layer 71.

In this configuration, too, in a MOSFET having the strained SiGe channel wherein the strained SiGe layer 62 is arranged on the convex of the Si substrate 5, the Si film 71 formed on the side of the SiGe layer 62 on the device isolation end prevents the side portion of the SiGe layer 62 from exposing to the device isolation end. Accordingly, increase of a leakage current occurring by the oxide film formed on the surface of the SiGe layer 62 can be prevented, and the present embodiment has the same effect as the first embodiment.

The present invention is not limited to the above embodiments. In the embodiments, the side wall of the SiGe layer is tapered, but the tapering is omitted when electric field convergence to a device isolation end has no problem. Further, the thickness t of the Si film on the side wall of the SiGe layer is not limited to 15 nm, but may changed appropriately according to a specification.

From a point of view to lower the surface Ge composition of the Si film sufficiently, the thickness t of the Si film may be more than 10 nm though it depends on conditions such as temperature or time employed in a MOS manufacturing process.

The effective Ge composition xeff for a lattice-relaxed SiGe used as the furring of a strained Si channel is set in value as previously described. However, when the SiGe layer is used as a channel, the Ge composition may be larger than the prescribed value. Further, a pure Ge channel is available.

According to the present invention, it can be prevented by forming a Si film on the side of a device isolation end that the side wall of the SiGe layer exposes to the device isolation end. Therefore, it can be prevented that the SiGe layer comes in contact with the oxide film directly. As a result, it can be prevented that the interface state of high-density occurs on the side wall of the SiGe layer, and a leakage current increases. Accordingly, reliability of a device improves.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A field effect transistor fabricated in a device isolation region, comprising:
a Si₁₋ₓGeₓ layer (0<x≦1) whose lattice strain is relaxed;
a strained Si layer formed on the Si₁₋ₓGeₓ;
a gate electrode insulatively disposed over a part of the strained Si layer;
source and drain regions formed in the strained Si layer with the gate electrode being arranged between the source and drain regions; and
a Si film covering side walls of the Si₁₋ₓGeₓ layer on ends of the device isolation region.

2. The field effect transistor according to claim 1, wherein an inner angle between a main surface of the Si₁₋ₓGeₓ layer and each of the side walls thereof makes an obtuse angle.

3. The field effect transistor according to claim 1, wherein the Si film on the side walls is formed of a Si film of not less than 10 nm in thickness.

4. A field effect transistor fabricated in a device isolation region, comprising:
a Si substrate;
a Si₁₋ₓGeₓ layer (0<x≦1) formed on the Si substrate;
a gate electrode insulatively disposed over a part of the Si₁₋ₓGeₓ layer;
source and drain regions formed in the Si₁₋ₓGeₓ layer with the gate electrode being arranged between the source and drain regions; and
a Si film covering side walls of the Si₁₋ₓGeₓ layer on ends of the device isolation region.

5. The field effect transistor according to claim 4, wherein the Si₁₋ₓGeₓ layer is formed of a strained Si₁₋ₓGeₓ layer.

6. The field effect transistor according to claim 4, which includes a Si cap layer formed on the Si₁₋ₓGeₓ layer.

7. The field effect transistor according to claim 4, wherein an inner angle between a main surface of the Si₁₋ₓGeₓ layer and each of the side walls thereof makes an obtuse angle.

8. The field effect transistor according to claim 4, wherein the Si film on the side walls is formed of a Si film of not less than 10 nm in thickness.

9. A field effect transistor device comprising:
an insulating film;
a Si₁₋ₓGeₓ layer (0<x≦1) formed in island on the insulating film and relaxed in lattice strain;
a strained Si layer formed on the Si₁₋ₓGeₓ layer and having a lattice strain;
a gate electrode insulatively disposed over a part of the strained Si layer;
source and drain regions in the strained Si layer with the gate electrode being arranged between the source and drain regions; and
a Si film covering side walls of ends of the Si₁₋ₓGeₓ layer.

10. The field effect transistor device according to claim 9, wherein an inner angle between a main surface of the Si₁₋ₓGeₓ layer and each of the side walls thereof makes an obtuse angle.

11. The field effect transistor according to claim 9, wherein the Si film is formed of a Si film of not less than 10 nm in thickness.

12-18. (canceled)
